(19) United States
(12) Patent Application Publication
(10) Pub. No.: US 2007/0134833 A1
(43) Pub. Date: Jun. 14, 2007

(54) Semiconductor element and method of making same

(75) Inventors: Yuhei Ikemoto, Aichi-ken (JP); Koji Hirata, Aichi-ken (JP); Kazuo Aoki, Tokyo (JP); Yukio Kaneko, Tokyo (JP); Takekazu Ujiie, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: TOYODA GOSEI CO., LTD., Aichi-ken (JP); KOHA CO., LTD., Tokyo (JP)

(21) Appl. No.: 11/636,709

(22) Filed: Dec. 11, 2006

(30) Foreign Application Priority Data
Dec. 14, 2005 (JP) 2005-360441
Mar. 1, 2006 (JP) 2006-055332
Jul. 7, 2006 (JP) 2006-187478

(51) Int. Cl. H01L 21/00

(52) U.S. Cl. 438/33

(57) ABSTRACT

A method of making a semiconductor element which has a substrate formed of gallium oxide and a semiconductor layer formed on the substrate. The method has: a first dividing step that the substrate with the semiconductor layer formed thereon is divided into a strip bar along a first cleaved surface of the substrate; and a second dividing step that the strip bar is divided in a direction perpendicular to the first cleaved surface.

The present application is based on Japanese patent application Nos. 2005-360441, 2006-055332 and 2006-187478, the entire contents of which are incorporated herein by reference.

### BACKGROUND OF THE INVENTION

1. Field of the Invention

This invention relates to a method of making a semiconductor element and, in particular, to a method of making a semiconductor element (chip) comprising a gallium oxide (Ga₂O₃) substrate and a semiconductor layer formed thereon. Also, this invention relates to the semiconductor element made by using the method.

2. Description of the Related Art

Group III nitride-based compound semiconductors are used for the manufacture of a short-wavelength light emitting element (or LED element). Such a light emitting element uses a transparent sapphire substrate. However, since the sapphire substrate is not conductive, the light emitting element need have a horizontal electrode structure which requires an etching process after the formation of a semiconductor layer on the substrate.

As such, a conductive and transparent substrate has been desired which is suited for growing the group III nitride-based compound semiconductor thereon.

In order to meet the desire, a gallium oxide (Ga₂O₃) substrate has been proposed (e.g., JP-A-2005-217437 and JP-A-2004-56098). The gallium oxide is monoclinic in crystal structure and conductive. Especially, since it is better lattice-matched to the group III nitride-based compound semiconductor than the trigonal sapphire, a high crystalline quality group III nitride-based compound semiconductor layer can be grown on a substrate formed of a bulk single-crystal gallium oxide.

On the other hand, wafer breaking is typically conducted by a dicing process using a dicer. Another wafer breaking process is known that a single-crystal SiC wafer with n-type layer and p-type layer of GaN formed thereon is divided into dice (or chips) by using the cleavage property (e.g., JP-A-2002-255692).

Further, a wafer breaking process is known that a wafer of oxide single crystal such as lithium niobate single crystal is divided into dice (or chips) by using the cleavage property and a thermal stress generated by short-pulse laser irradiation (e.g., JP-A-10-305420 and JP-A-11-224865).

The inventors study the wafer breaking process of semiconductor elements formed of gallium oxide, and find the following problems.

Gallium oxides, especially β-Ga₂O₃ have a strong cleavage property and its (100)-plane and (001)-plane have the cleavage property. Thus, when the wafer is divided into dice, the substrate may be peeled off to damage the die. In other words, it is difficult to break the wafer into dice even though a high-quality group III nitride-based compound semiconductor layer can be formed on the substrate.

Thus, since the gallium oxide substrate has significant difference in cleavage property depending on the plane direction, it is very difficult to break the wafer at a high product yield by the dicing process. In particular, the β-Ga₂O₃ has a cleavage property further in a direction parallel to the substrate surface where the semiconductor layer is formed. Therefore, when the wafer is cut by the dicing process, peeling or a crack can be easy caused in the vicinity of the cutting face.

The above wafer breaking processes disclosed in JP-A-2002-255692, JP-A-10-305420 and JP-A-11-224865 are conducted to divide the wafer into dice by using the cleavage property at all surfaces thereof. Therefore, they are not suited to the breaking process of a semiconductor wafer using the gallium oxide substrate that has significant difference in cleavage strength depending on the plane direction.

### SUMMARY OF THE INVENTION

It is an object of embodiments according to the invention to provide a method of making a semiconductor element that can produce the semiconductor element (i.e., chip), which comprises a gallium oxide (Ga₂O₃) substrate and a semiconductor layer formed thereon, at a high product yield without causing the peeling or crack in the vicinity of the processed part.

(1) According to one embodiment of the invention, a method of making a semiconductor element that comprises a substrate formed of gallium oxide and a semiconductor layer formed on the substrate comprises:

a first dividing step that the substrate with the semiconductor layer formed thereon is divided into a strip bar along a first cleaved surface of the substrate; and

a second dividing step that the strip bar is divided in a direction perpendicular to the first cleaved surface.

In accordance with the above embodiment method (1), the substrate is divided by positively using the cleavage property of the first cleaved surface to obtain the strip bar. Therefore, the cleavage property does not obstruct the dividing of the substrate.

Then, if the strip bar is cut perpendicular to the semiconductor layer forming surface (or the opposite surface) as conducted in the conventional dicing process when dividing the strip bar into the dice, stress is applied in the direction of a second cleaved surface (perpendicular to the first cleaved surface and parallel to the semiconductor layer forming surface. Thus, the substrate may be peeled or the semiconductor layer may be subjected to excessive stress. In contrast, in the above embodiment method (1), the strip bar is cut perpendicular to the first cleaved surface, and therefore stress applied in the direction of the second cleaved surface can be reduced significantly. Thus, the peeling of the substrate can be prevented and the stress to the semiconductor layer can be reduced. Therefore, the element dividing can be conducted smoothly and the element can be made at high throughput and product yield.

In the above embodiment method (1), it is preferred that the second dividing step includes a marking step. A mark provided by the marking step defines a divide line of the strip bar and serves as a reference for the divide line. For example, the divide line is formed on the side of the semiconductor layer forming surface of the strip bar, and then the strip bar is cut perpendicular to the first cleaved surface by using the divide line as a guide.

The divide line (=mark) may be provided as the shallow groove formed by dicing as mentioned later in the embodiment or as painted line if recognizable from the side face (=first cleaved surface) of the strip bar. Also, the painted line can be formed on the side face of the strip bar. Further, since the chip size is predetermined, by providing a certain reference point, the chip dividing can be continuously conducted at intervals of the chip size from the reference point. The reference point can be provided by dicing or painting. Further, the marking can be conducted by laser or dry etching. The mark can be also formed on the opposite surface to the semiconductor layer forming surface.

The second dividing step includes a dicing step. In the dicing step, the strip bar is diced perpendicular to the first cleaved surface (first dicing step). The strip bar is thus diced to a predetermined depth from one side face (=first cleaved surface), reversed 180 degrees, and diced from the other side face (second dicing step) to complete the dividing of the strip bar. In this case, the mark formed on the surface (=semiconductor layer forming surface) of strip bar can allow the easy and accurate positioning for the first and second dicing steps. By thus dicing the strip bar from the opposite side-face directions, stress to the substrate or semiconductor layer can be reduced.

In the above embodiment method (1), the gallium oxide substrate is made by slicing a bulk crystal obtained by the known method such as EFG and FZ into a wafer, and has β structure in gallium oxide crystal. In case of β-Ga₂O₃ substrate, the substrate surface (on which to form the group III nitride-base compound semiconductor layer) is selected to have (100), (010), (001) or (801) plane. The strong cleavage property appears on the (100) and (010) planes. The β-Ga₂O₃ is conductive and transparent regardless of its plane direction.

A high crystalline-quality group III nitride-base compound semiconductor layer can be epitaxially grown on the gallium oxide substrate. The group III nitride-base compound semiconductor is represented by a general formula: AlₓGa_{y}In_{1-x-y}N (0≦X≦1, 0≦Y≦1, 0≦X+Y≦1) as a four-element system, and includes a two-element system such as GaN and InN, and a three-element system such as AlₓGa₁₋ₓN, AlₓIn₁₋ₓN and GaₓIn₁₋ₓN (for all 0<X<1). Apart of the group III element can be replaced by boron (B), thallium (Ta) etc., and a part of nitrogen (N) can be replaced by phosphorous (P), arsenic (As), antimony (Sb), bismuth (Bi) etc.

A semiconductor layer except the group III nitride-base compound semiconductor layer can be also grown on the gallium oxide substrate.

(2) According to another embodiment of the invention, a semiconductor element comprises:

a substrate formed of gallium oxide and comprising a predetermined plane direction; and

a semiconductor layer formed on the substrate,

wherein the semiconductor element is in chip form and further comprises a first end face formed along a cleaved surface of the substrate and a second end face formed perpendicular to the first end face, and

the first end face comprises a stronger cleavage property than the second end face.

In the above embodiment (2), the following modifications and changes can be made.

(i) The substrate is formed of β-Ga₂O₃.

(ii) The second end face is formed by dicing.

(iii) The second end face is formed by a laser processing to irradiate a laser light with a predetermined wavelength.

(iv) The predetermined plane direction comprises at least one of (100), (001), (010) and (801) plane directions.

(3) According to another embodiment of the invention, a method of making a semiconductor element comprises the steps of:

forming a semiconductor layer on a gallium oxide substrate with a predetermined plane direction;

cleaving the gallium oxide substrate into a strip bar along a cleaved surface thereof; and

cutting the strip bar in a direction perpendicular to the cleaved surface by using a process except the cleaving.

In the above embodiment (3), the following modifications and changes can be made.

(v) The process comprising a dicing process.

(vi) The process comprising a laser processing to irradiate a laser light with a predetermined wavelength.

(vii) The predetermined wavelength comprises a wavelength of less than 400 nm.

(viii) The predetermined wavelength comprises a wavelength obtained by the laser light comprising a YAG third harmonic wave or excimar laser.

(ix) The predetermined plane direction comprises at least one of (100), (001), (010) and (801) plane directions.

(4) According to another embodiment of the invention, a method of making a semiconductor element comprises:

an element forming step that a first conductivity type semiconductor layer and a second conductivity type semiconductor layer are on a substrate formed of gallium oxide (Ga₂O₃); and

a dicing step that the substrate with the first and second conductivity type semiconductor layers is divided into the semiconductor element by applying a plurality of dicing processes for each diced portion.

(5) According to another embodiment of the invention, a method of making a semiconductor element comprises:

an element forming step that a first conductivity type semiconductor layer and a second conductivity type semiconductor layer are on a substrate formed of gallium oxide (Ga₂O₃);

a first dicing step that the substrate is diced in a first direction; and

a second dicing step that the substrate is diced in a second direction opposite to the first direction such that the substrate with the first and second conductivity type semiconductor layers is divided into the semiconductor element.

(6) According to another embodiment of the invention, a method of making a semiconductor element comprises:

an element forming step that a first conductivity type semiconductor layer and a second conductivity type semiconductor layer are on a substrate formed of gallium oxide (Ga₂O₃);

a first dicing step that the substrate is diced at a first dicing width in a first direction; and

a second dicing step that the substrate is diced with a second dicing width in the first direction such that the substrate with the first and second conductivity type semiconductor layers is divided into the semiconductor element.

In the above embodiment (5) or (6), the following modifications and changes can be made.

(x) The first and second dicing steps are conducted with a same dicing width (e.g., 20 μm).

(xi) The first dicing width (e.g., 50 μm) is greater than the second dicing width (e.g., 20 μm).

Definitions of Terms

Herein, “dicing” means a process that cut grooves (by full cutting or half cutting) are formed like a lattice in a wafer so as to divide the wafer into dice (or chips). “scribing” means a process that a scratch (or a scribe line) is formed on the surface of a wafer by a diamond cutter etc. while using its cleavage property so as to divide the wafer into dice (or chips). “breaking” means a process that a wafer is cracked along a cut groove or a scratch formed on the wafer so as to divide the wafer into dice (or chips).

### BRIEF DESCRIPTION OF THE DRAWINGS

The preferred embodiments according to the invention will be explained below referring to the drawings, wherein:

FIG. 1 is a cross sectional view showing a semiconductor element (as a wafer or chip), which has a β-Ga₂O₃ substrate and semiconductor layers formed thereon, in a first or third preferred embodiment of the invention;

FIGS. 2A and 2B are schematic plain views showing a first dividing step in the first embodiment;

FIG. 3 is a schematic perspective view showing a second dividing step (i.e., a marking step) in the first embodiment;

FIG. 4 a schematic perspective view showing another second dividing step (i.e., a first dicing step) in the first embodiment;

FIG. 5 a schematic perspective view showing another second dividing step (i.e., a second dicing step) in the first embodiment;

FIG. 6 is a perspective view showing a gallium oxide substrate, on which a light emitting element is formed, in a second preferred embodiment of the invention;

FIG. 7 is an illustration showing a MOCVD method;

FIG. 8 is a cross sectional view showing an LED element;

FIG. 9 is a perspective view showing a process that a β-Ga₂O₃ substrate with semiconductor layers formed thereon is cleaved along a predetermined cleavage region to have a strip chip with the β-Ga₂O₃ substrate;

FIG. 10 is a perspective view showing a process that the strip chip made by cleaving is divided into chips by a diamond blade;

FIG. 11 is a perspective view showing a process that the strip chip made by cleaving is divided into chips by laser processing instead of the diamond blade;

FIGS. 12A to 12E are cross sectional views showing a method of making a semiconductor element (LED element) in a third preferred embodiment of the invention;

FIGS. 13A to 13C are cross sectional views showing a process that a bar (or a strip) with Ga₂O₃ substrate is divided into chips by a dicing blade;

FIGS. 14A to 14C are cross sectional views showing a method of making a semiconductor element (LED element) in a fourth preferred embodiment of the invention; and

FIG. 15 is a plain view showing a modification of the third or fourth embodiment.

### DETAILED DESCRIPTION OF THE PREFERRED EMBODIMENTS

### First Embodiment

A method of making a semiconductor element in the first embodiment will be explained below.

Formation of Semiconductor Layer

A wafer of β-Ga₂O₃ is placed in an MOCVD apparatus and its surface is at first nitrided. The nitriding method is not specifically limited and, for example, the wafer of β-Ga₂O₃ may be heated in ammonium atmosphere. Then, group III nitride-based compound semiconductor layers are on its (100)-plane by an ordinary method.

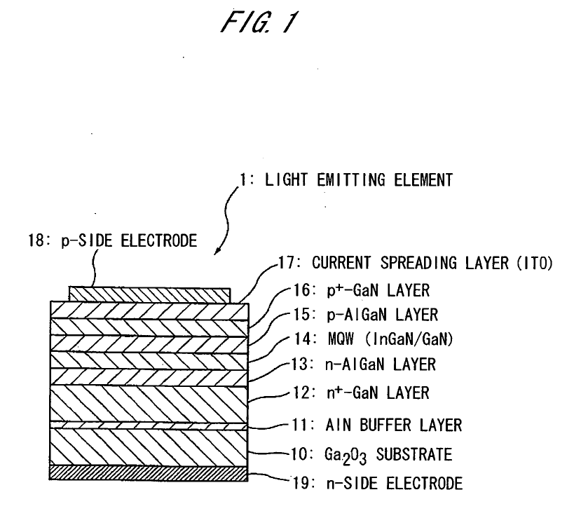

In this embodiment, the semiconductor element has a layer structure as mentioned below so as to compose a light emitting element (or LED element) (See FIG. 1). FIG. 1 is illustrated to show the layer structure and does not precisely show the film thickness of each layer thereof.

| Layer | Composition |
|---|---|
| p-contact layer 16 | p⁺-GaN |
| p-cladding layer 15 | p-AlGaN |
| MQW light emitting layer 14 | InGaN/GaN |
| n-cladding layer 13 | n-AlGaN |
| n-contact layer 12 | n⁺-GaN |
| buffer layer 11 | AlₓGa₁₋ₓN (0.5 ≦ x ≦ 1) |
| substrate 10 | β-Ga₂O₃ |

As described earlier, the β-Ga₂O₃ substrate is heated at 600 to 110° C. for several minutes in the ammonium atmosphere. Thereby the surface is nitrided.

The buffer layer is formed by MOCVD using hydrogen gas as a carrier gas and at relatively low temperature of about 350 to 550° C. The AlₓGa₁₋ₓN buffer layer is desirably made Al rich.

Although in this embodiment the n-type layer is formed of GaN, it may be formed of another group, III nitride-based compound semiconductor such as AlGaN, InGaN and AlInGaN. An n-type dopant to be doped into the n-type layer can be Si, Ge, Se, Te, C etc.

The p-type layer can be also formed of the group III nitride-based compound semiconductor as mentioned above. A p-type dopant to be doped into the p-type layer can be Mg, Zn, Be, Ca, Sr, Ba, etc.

Although in this embodiment the group III nitride-based compound semiconductor layers are fabricated by MOCVD, it can be also fabricated by MBE (molecular beam epitaxy), HVPE (halide vapor phase epitaxy), sputtering, ion-plating, electron shower etc.

A current spreading layer 17 of ITO (indium tin oxide) is formed on the p-contact layer. P-side electrode 18 of gold is formed on the current spreading layer 17. An n-side electrode 19 of aluminum is formed on the back surface (i.e., a surface opposite to the surface on which the semiconductor layers are formed) of the β-Ga₂O₃ substrate 10. Since the β-Ga₂O₃ substrate 10 is electrically conductive, the p-side electrode 18 and the n-side electrode 19 can be thus formed vertically so that the fabrication process of the LED element can be simplified.

First Dividing Step

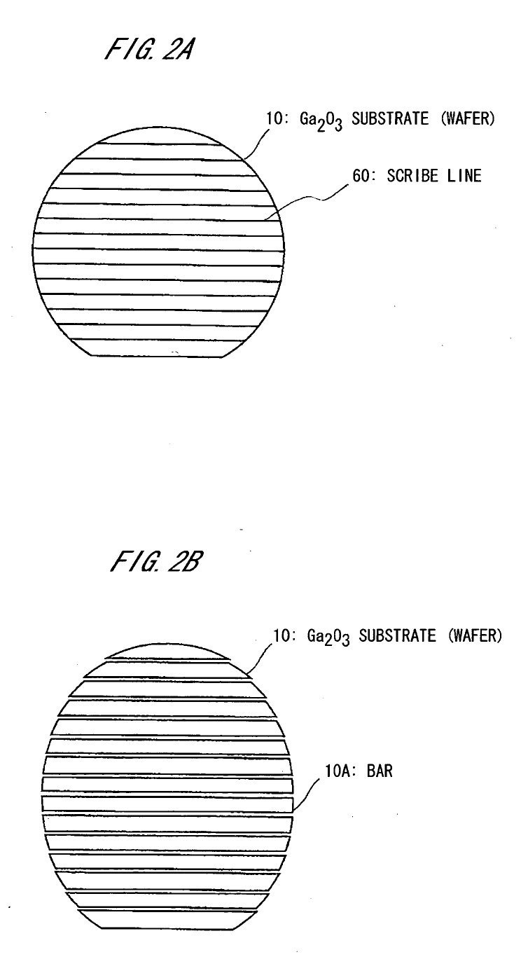

The β-Ga₂O₃ wafer with the semiconductor layers formed thereon is divided (or separated) like a strip along a (001)-plane (i.e., first cleaved surface) thereof to have bars 10A (See FIG. 2B). One of the bars 10A has a width equal to the width of the element (or chip). In other words, continuously connecting the elements (or chips) in one dimension composes the bar 1A. In making the bar 10A, scribe lines 60 (See FIG. 2A) are formed which reach the substrate from the surface (i.e., semiconductor formation surface) of the wafer. The scribe line 60 is formed along the first cleaved surface of the substrate. Then, the wafer 10 is divided into the strip-shaped bars 10A by breaking along the scribe line 60.

Since the first dividing step is conducted along the first cleaved surface of the substrate, stress is little applied to the substrate. Therefore, the damage of the substrate and the semiconductor layer can be prevented.

Second Dividing Step (Marking Step)

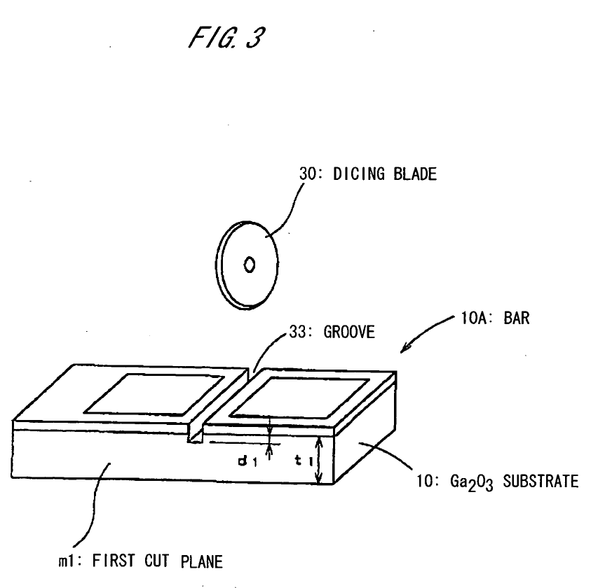

First, as shown in FIG. 3, a shallow groove 33 is formed on the surface side of each bar 10A by using a dicing blade 30. The groove 33 is a mark to serve as a position guide for a dicing step conducted later. The depth of the groove 33 is not specifically limited if it is a depth such as not to apply any stress to the substrate. For example, the depth d1 of the groove 33 is preferably 0<d1≦0.5t1 where t1 is the thickness of the substrate 10.

The groove 33 is formed on a cut portion, i.e., an edge of the chip, along which the bar 10A is cut into the chip.

In FIG. 3, a first cut plane (i.e., first cleaved surface) is indicated by a symbol m1.

Second Dividing Step (First Dicing Step)

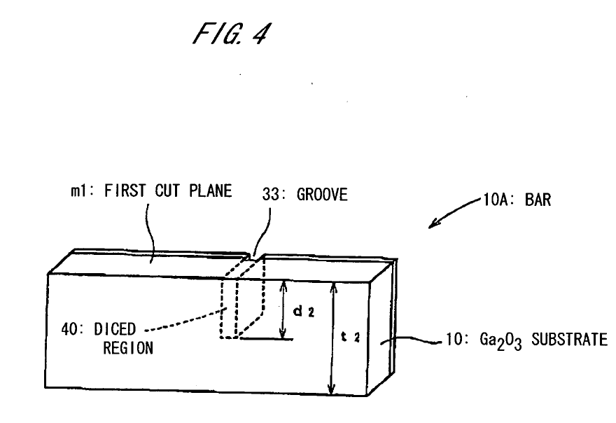

The bar 10A marked with the shallow groove 33 formed thereon is rotated 90 degrees to turn the first cut plane m1 upward (FIG. 4). Dicing is conducted on the side of the first cut plane m1. A region to be diced on the first dicing step is indicated by a numeral 40. In the dicing, the groove 33 serves as a guide. Thus, positioning in the dicing can be accurately and easily conducted. If the groove 33 is not formed, it is difficult to determine accurately the dividing position of the chip since the first release surface is flat.

The depth d2 of a groove to be formed on the first dicing step is preferably 0.2t2<d2≦0.8t2 where t2 is the width of the bar 10A as shown in FIG. 4.

Second Dividing Step (Second Dicing Step)

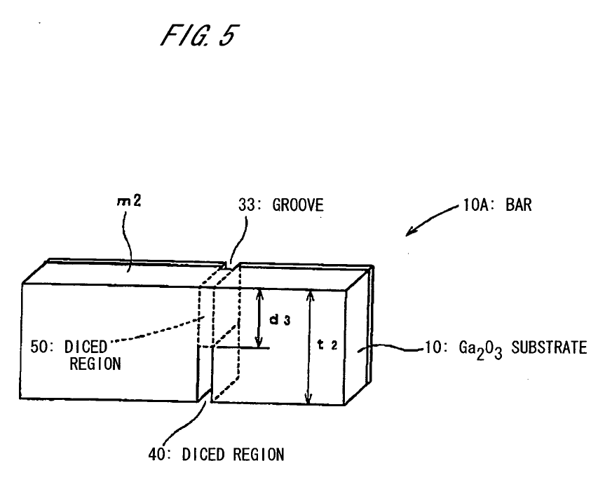

Then, as shown in FIG. 5, the bar 10A is rotated 180 degrees to turn the first cut plane m1 downward. Then, dicing is conducted on the other side plane m2 (i.e., this plane m2 also corresponding to the first cut plane) of the bar 10A. In this case, the groove 33 serves as a guide to conduct the dicing accurately. A region to be diced on the second dicing step is indicated by a numeral 50. The depth d3 of a groove to be formed on the second dicing step is preferably 0.2t2<d3≦0.8t2 where t2 is the width of the bar 10A as shown in FIG. 4.

Thus, the dicing is completed. Then, the bar 10A is divided (or separated) into the chips by breaking.

Then, the chip thus made can be mounted on a wiring substrate directly or through a submount according to use.

### Second Embodiment

Gallium Oxide Substrate

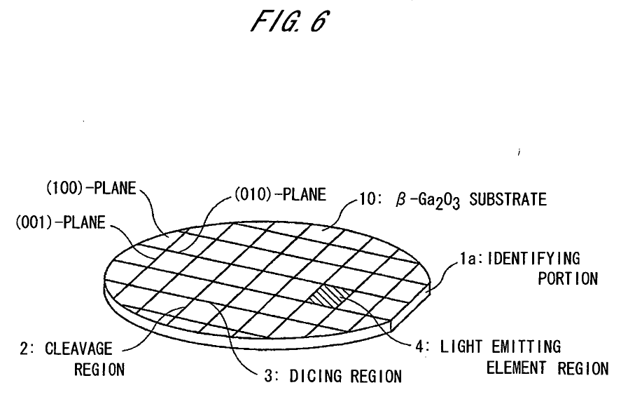

FIG. 6 shows the gallium oxide substrate on which a light emitting element (LED element) is formed.

The β-Ga₂O₃ substrate 10 as the gallium oxide substrate is a substrate that is processed into a wafer with a predetermined plane direction. In case of the β-Ga₂O₃ substrate 10, the substrate surface is set (100), (010), (001)-plane or (801)-plane, and has a strong cleavage property at the (100)-plane. As described above, when the substrate surface is set (100), (010), (001)-plane or (801)-plane, the cleavage property is also recognized at the (001)-plane.

In growing the light emitting element on the β-Ga₂O₃ substrate 10, the substrate surface is set the (100)-plane or (801)-plane so as to facilitate the wafer processing and the formation of the light emitting element. In this case, the wafer is cleaved along the (001)-plane by using the cleavage property and cut along the (010)-plane by dicing etc., so that a number of the light emitting elements formed on the β-Ga₂O₃ substrate 10 are divided as a bare chip.

It is preferred that an identifying portion 1a such as a notch, a groove and an orientation flat is formed to identify the plane direction of the β-Ga₂O₃ substrate 10.

Formation of Light Emitting Element

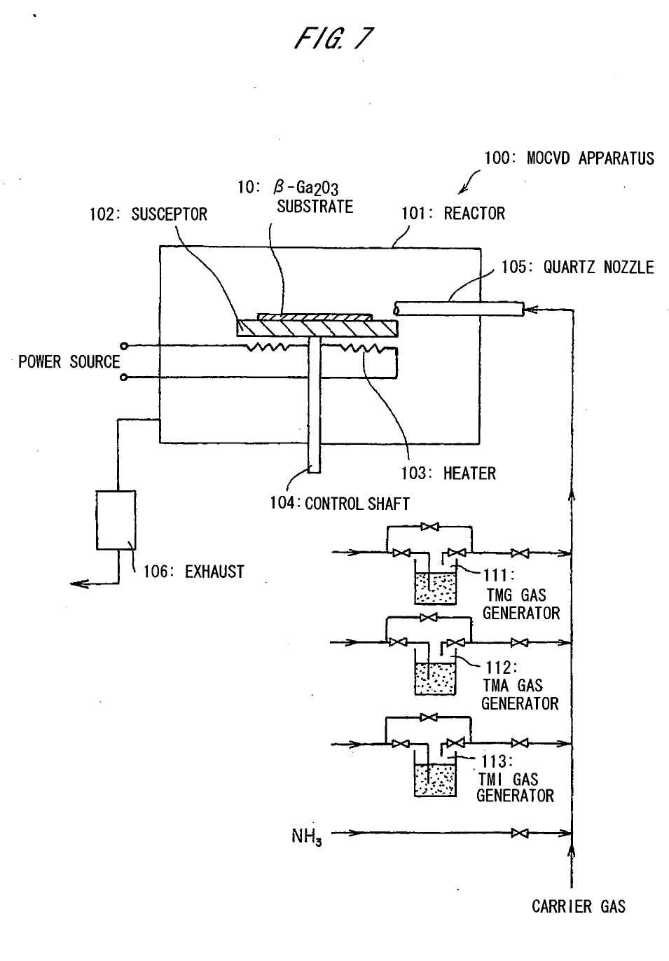

FIG. 7 illustrates an MOCVD method. An MOCVD apparatus 100 comprises: a reactor 101 to which an exhaust 106 with a vacuum pump and an exhausting unit (neither shown); a susceptor 102 on which a β-Ga₂O₃ substrate 10 is placed, a heater 103 to heat the susceptor 102; a control shaft 104 to control the rotation and vertical movement of the susceptor 102; a quartz nozzle 105 to supply a source gas diagonally or horizontally to the β-Ga₂O₃ substrate 10; and gas generators to generate various source gases, i.e., a TMG (trimethyl gallium) gas generator 111, a TMA (trimethyl aluminum) gas generator 112 and a TMI (trimethyl indium) gas generator 113. The number of the gas generators can be increased or reduced if necessary. NH₃ is used as a nitrogen source and H₂ is used as a carrier gas. TMG and NH₃ are used to grow a GaN film, TMA, TMG and NH₃ are used to grow an AlGaN film, and TMI, TMG and NH₃ are used to grow an InGaN film.

The film formation by the MOCVD apparatus 100 is conducted such that the β-Ga₂O₃ substrate 10 is mounted on the susceptor 102 with the film forming surface facing up, and placed in the reactor 101.

In this case, the β-Ga₂O₃ substrate 10 is mounted on the susceptor 102 such that a light emitting element can be formed at a predetermined position in a rectangular region, i.e., a light emitting element region 4, surrounded by a cleavage region 2 and a dicing region 3 (See FIG. 6).

Structure of the LED Element

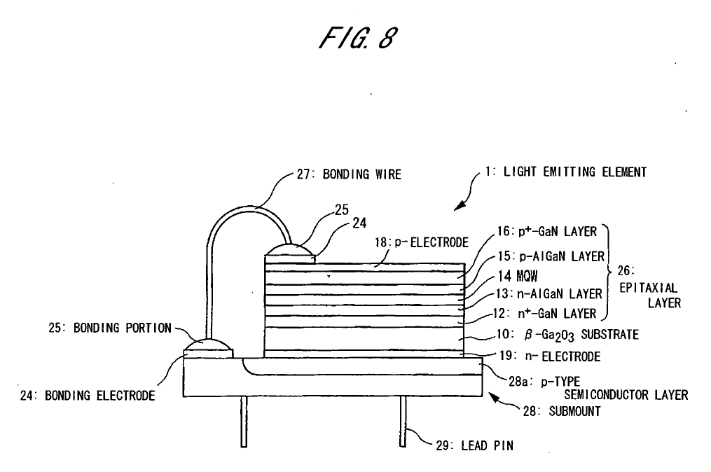

FIG. 8 shows the structure of the LED element 1.

The LED element 1 comprises: sequentially formed on the β-Ga₂O₃ substrate 10 with n-type conductivity, a Si-doped n⁺-GaN layer 12; a Si-doped n-AlGaN layer 13; MQW (multiquantum well) 14 with a multiquantum well structure formed of InGaN/GaN; a Mg-doped p-AlGaN layer 15; a Mg-doped p⁺-GaN layer 16; a p-electrode 18 formed of ITO (indium tin oxide); and an n-electrode 19 formed under the β-Ga₂O₃ substrate 10.

The n⁺-GaN layer 12 and the p⁺-GaN layer 16 are each grown by supplying NH₃ and TMG as well as H₂ as a carrier gas into the reactor, in which the β-Ga₂O₃ substrate 10 is placed, at growth temperature of 1100° C. Further, with respect to the n⁺-GaN layer 12, monosilane (SiH₄) is used as a Si source (n-dopant) to yield n-type conductivity. With respect to the p⁺-GaN layer 16, cyclopentadienyl magnesium (Cp₂Mg) is used as a Mg source (p-dopant) to yield p-type conductivity. The n-AlGaN 13 and the p-AlGaN 15 are grown by supplying TMA as well as NH₃ and TMG into the reactor.

The MQW 14 is grown by supplying TMI and TMG as well as NH₃, N₂ as a carrier gas into the reactor at growth temperature of 1100° C. In detail, TMI and TMG as well as NH₃ are supplied to grow the InGaN and TMG as well as NH₃ are supplied to grow the GaN.

Fabrication Process of LED Element (in Wafer Form)

First, the β-Ga₂O₃ substrate 10 is placed on the susceptor of the MOCVD apparatus.

Then, it is heated to a predetermined temperature (400° C.) and N₂ is supplied thereinto. Then, the reactor temperature is increased to 1100° C. and kept at that temperature. In this state, TMG is supplied 60 sccm to form the 1 μm thick n⁺-GaN layer 12. Then, the N₂ supply into the reactor is stopped and H₂ is supplied.

After that, the n-AlGaN layer 13, the MQW 14, the p-AlGaN layer 15, the p⁺-GaN layer 16, the p-electrode 18 and the n-electrode 19 are sequentially grown. The explanations of the growth process thereof are omitted.

Dividing of the Ga₂O₃ Substrate by Cleaving

The fabricated β-Ga₂O₃ substrate 10 (in wafer form) with the semiconductor layers formed thereon is checked in electrical characteristics and failure and then cleaved by using the cleavage property.

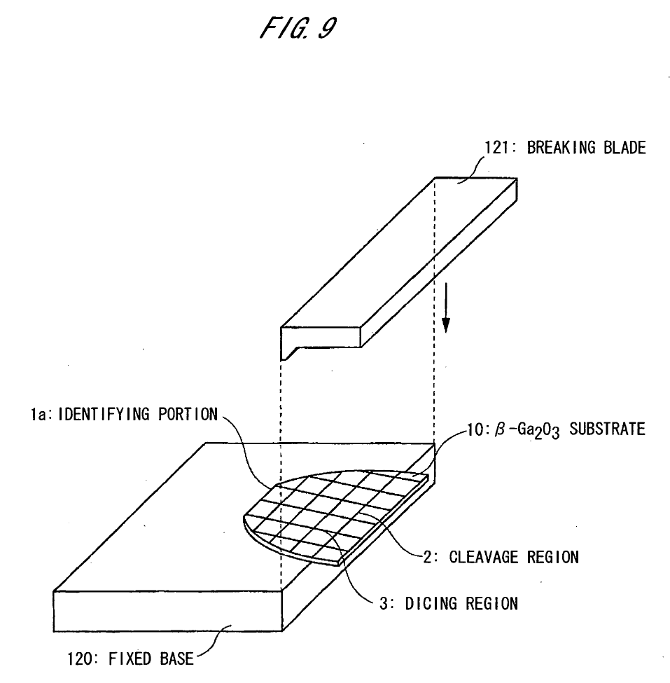

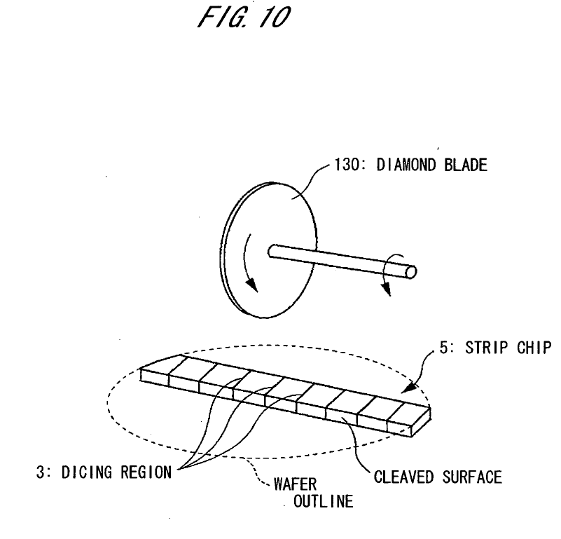

FIG. 9 is a perspective view showing the cleaving process that the β-Ga₂O₃ substrate 10 with the semiconductor layers formed thereon is cleaved along a predetermined cleavage region to have a strip chip with the β-Ga₂O₃ substrate. The β-Ga₂O₃ substrate 10 is fixed at a predetermined position of a fixed base 120 while identifying the cleavage direction by the identifying portion 1a. A cleaving blade (or breaking blade) 121 is positioned to be aligned with the cleavage region 2, and then the cleaving blade 121 is pressed down to apply a predetermined shear force to the cleavage region 2 to cleave the wafer along the cleavage region 2. By repeating these steps, the β-Ga₂O₃ substrate 10 with the semiconductor layers formed thereon is divided into strip chips 5 (See FIG. 10).

Dividing of the Ga₂O₃ Substrate by Dicing

FIG. 10 is a perspective view showing the dicing process that the strip chip 5 made by cleaving is diced into chips by a diamond blade 130. In this process, the diamond blade 130 cuts the strip chip 5 along a dicing region 3 while being rotated. The cutting direction or region is set to be in the direction of small cleavage property or no cleavage. Thus, the strip chip 5 can be diced into chips, each of which composing the light emitting element, without causing any defects such as chipping.

(Modification) Dividing of the Ga₂O₃ Substrate by Laser

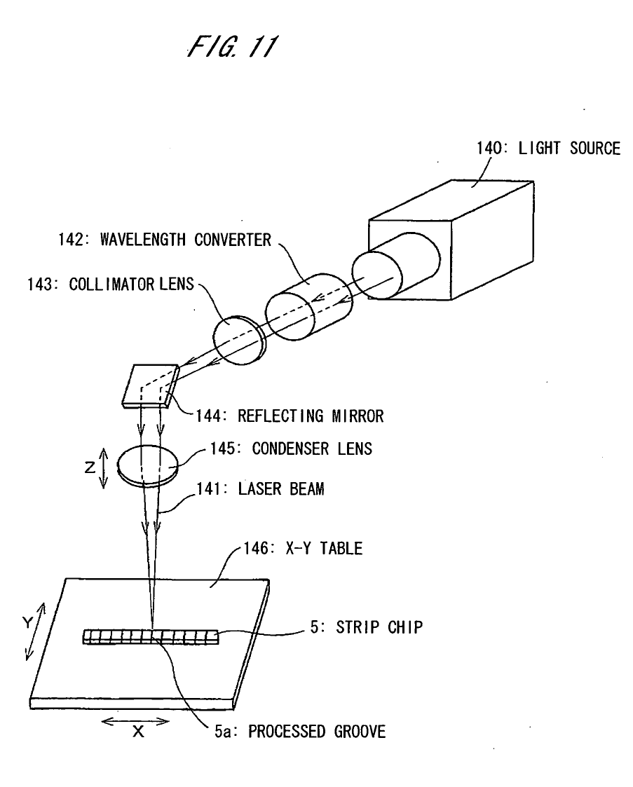

FIG. 11 is a perspective view showing a process that the strip chip 5 made by cleaving is divided into chips by laser processing instead of the dicing process (by the diamond blade).

A YAG laser as a light source 140 is driven under given conditions to emit a laser beam 141. It is driven by continuous Q switch oscillation. The emitted laser beam 141 is converted into third harmonic wave with a wavelength of 355 nm by a wavelength converter 142, processed into parallel light by a collimator lens 143, reflected on a reflecting mirror 144, and controlled to focus the surface of the strip chip 5 or a predetermined position in Y direction from the surface thereof by moving a condenser lens 143 in the optical axis direction.

The laser processing is conducted by suitably setting the laser output, oscillating frequency, processing speed in the X direction and Y direction, and number of scanning. For example, as shown in FIG. 11, an X-Y table 146 is moved in the Y direction such that the laser beam 141 is irradiated onto the surface of the strip chip 5 by a preset number of scanning to form a given number of processed grooves 5a for the breaking or cutting while being shifted in the X direction for each groove 5a.

The third harmonic wave of the YAG laser has a wavelength of 355 nm, and about 30% thereof is absorbed into the β-Ga₂O₃ in view of its optical transmission spectrum. As a result, the laser beam 141 irradiated onto the surface of the strip chip 5 contributes not only to the thermal processing to heat and melt the processed part, but also to the laser abrasion to cut at least a part of the intermolecular bond of the β-Ga₂O₃ such that the processed part is scattered and removed by being gasified or broken into fine particles.

The processing wavelength of the laser beam 141 from the light source 140 is not limited to 355 nm and may be in the range of 400 nm or less that causes the optical absorption to enable the above laser processing of the substrate.

By applying a given force along the processed groove 5a, the strip chip 5 can be divided into chips with a necessary shape. Instead, when the processed groove 5a is made penetrating the strip chip 5, the strip chip 5 can be divided into chips with a necessary shape without applying the given force.

Alternatively, in case of the wafer 10 rather than the strip chip 5, after processing a given number of grooves 5a needed for the breaking or cutting in the X or Y direction by the laser beam 141, the X-Y table 146 can be then moved in the Y or X direction perpendicular to the above direction such that the laser beam 141 is irradiated onto the surface of the wafer 10 to form a given number of grooves 5a in the Y or X direction. Thus, the processed grooves 5a for the breaking or cutting can be formed like a lattice on the surface of the wafer 10. Then, by applying a given force along the processed groove 5a, the wafer 10 can be divided into chips with a necessary shape.

Assembling of Light Emitting Device

Each of bare chips thus obtained by cleaving, breaking or cutting from the β-Ga₂O₃ substrate 10 (in wafer form) is used to assemble a light emitting device.

The light emitting element (or chip) comprising the β-Ga₂O₃ substrate 10, the n-electrode 19, the epitaxial layer 26 and the p-electrode 18 is mounted, through a conductive metal paste etc., on a submount 28 with lead pins 29 to be inserted into a circuit board etc. The submount 28 is formed of an n-type silicon substrate which operates as a Zener diode to protect the LED element 1 from static electricity. The n-electrode 19 is electrically connected to a p-type semiconductor layer 28a formed on the submount 28. The p-electrode 18 is electrically connected through a bonding electrode 24, a bonding portion 25 and a bonding wire 27 to the submount 28. Thus, the light emitting device is assembled which can be mounted on a circuit board etc.

Effects of the Second Embodiment

In the second embodiment, the light emitting element (in chip form) formed on the gallium oxide substrate can be divided without causing the peeling or crack in the vicinity of the processed part. Especially in case of the β-Ga₂O₃ substrate having the planes with different cleavage strengths, the substrate is first divided along one plane (with high cleavage property) by the cleaving to provide a smooth surface and is then divided along the other plane (with low cleavage property) by the dicing or laser processing. Thereby, the product yield can be increased to enhance the productivity. Thus, this embodiment is characterized in that, for the semiconductor element (in wafer form) comprising the gallium oxide (Ga₂O₃) and the semiconductor layer formed thereon, the dividing process is conducted by cleaving in the direction of strong cleavage property and by dicing etc. except the cleaving in the direction of weak cleavage property.

Although in the second embodiment the light emitting element is an LED element, a laser element can be formed by the same process. In this case, a cleaved surface thereof can be used as an optical resonator.

### Third Embodiment

FIG. 1 is a cross sectional view showing a nitride semiconductor element, i.e., a group III nitride-based compound semiconductor light emitting element (hereinafter simply called ‘light emitting element’), in the third preferred embodiment of the invention.

Structure of Light Emitting Element

The light emitting element 1, which is a vertical type light emitting element with p- and n-side electrodes disposed in vertical direction, comprises: a Ga₂O₃ substrate 10 as a growth substrate for growing group III nitride-based compound semiconductor thereon; and, sequentially formed on the Ga₂O₃ substrate 10, an AlN buffer layer 11; a Si-doped n⁺-GaN layer 12; a Si-doped n-AlGaN layer 13; MQW (multiquantum well) 14 with a multiquantum well structure formed of InGaN/GaN; a Mg-doped p-AlGaN layer 15; a Mg-doped p⁺-GaN layer 16; and a current spreading layer 17 formed of ITO (indium tin oxide) to spread current into the p⁺-GaN layer 16. The AlN buffer layer 11 to the p⁺-GaN layer 16 are grown by MOCVB (metalorganic chemical vapor deposition).

The light emitting element 1 further comprises a p-electrode 18 of gold formed on the current spreading layer 17, and an n-electrode 19 of aluminum formed under the Ga₂O₃ substrate 10.

The Ga₂O₃ substrate 10 of this embodiment has transparency in the range of blue to ultraviolet and is formed of β-Ga₂O₃ obtained as a bulk single crystal with a diameter of 2 inches by the EFG or FZ method.

The AlN buffer layer 11 is grown by supplying NH₃ and TMA (trimethyl aluminum) as well as H₂ as a carrier gas into the reactor in which the Ga₂O₃ substrate 10 is placed.

The n⁺-GaN layer 12 and the p⁺-GaN layer 16 are grown by supplying NH₃ and TMG (trimethyl gallium) as well as H₂ as a carrier gas into the reactor in which the Ga₂O₃ substrate 10 is placed. Further, with respect to the n⁺-GaN layer 12, monosilane (SiH₄) is used as a Si source (n-dopant) to yield n-type conductivity. With respect to the p⁺-GaN layer 16, cyclopentadienyl magnesium (Cp₂Mg) is used as a Mg source (p-dopant) to yield p-type conductivity. The n-AlGaN 13 and the p-AlGaN 15 are grown by supplying TMA as well as NH₃ and TMG into the reactor.

The MQW 14 is grown by supplying TMI and TMG as well as NH₃, N₂ as a carrier gas into the reactor. In detail, TMI and TMG as well as NH₃ are supplied to grow the InGaN and TMG as well as NH₃ are supplied to grow the GaN.

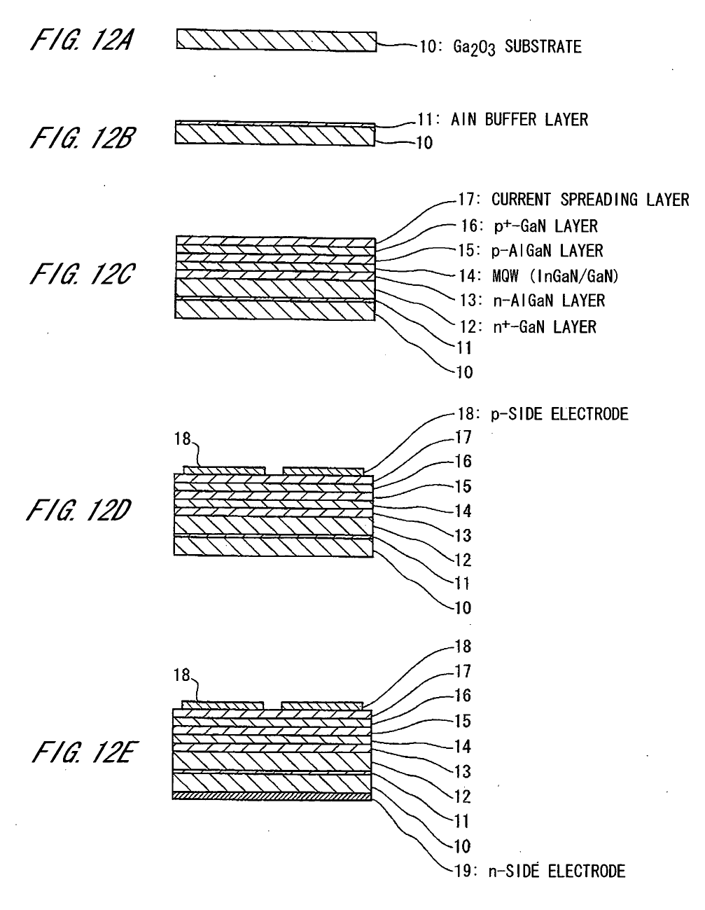

FIGS. 12A to 12E are cross sectional views showing a method of making the light emitting element of the third preferred embodiment.

First, as shown in FIG. 12A, the Ga₂O₃ substrate 10 (in wafer form) formed of a bulk single crystal β-Ga₂O₃ is provided and placed on the susceptor in the reactor.

Then, as shown in FIG. 12B, TMA and NH₃ as well as H₂ a carrier gas are supplied onto the surface of the Ga₂O₃ substrate 10 placed in the reactor at growth temperature of 400° C. to grow the AlN buffer layer 11.

Then, as shown in FIG. 12C, the GaN-based semiconductor layers, the n⁺-GaN layer 12 through the p⁺-GaN layer 16, are grown on the AlN buffer layer 11 by MOCVD and the current spreading layer 17 is formed on the p⁺-GaN layer 16 by sputtering.

Then, as shown in FIG. 12D, the p-side electrode 18 of gold is formed on the current spreading layer 17 by deposition.

Then, as shown in FIG. 12E, the n-side electrode 19 of aluminum is formed on the back surface (on which the semiconductor layers are not formed) of the Ga₂O₃ substrate 10. Meanwhile, the wafer with the GaN-based semiconductor layers is reversed to form the n-side electrode 19.

FIGS. 2A to 2B are schematic plain views showing a dividing step of the Ga₂O₃ substrate 10 (in wafer form) with the GaN-based semiconductor layers. FIG. 2A shows a state before dividing the Ga₂O₃ substrate 10, and FIG. 2B shows a state after dividing the Ga₂O₃ substrate 10.

In dividing the wafer Ga₂O₃ substrate 10, it is first divided into bars to expose a cleaved surface of β-Ga₂O₃. In detail, as shown in FIG. 2A, scribe lines 60 are formed along the cleavage direction of the Ga₂O₃ substrate 10. Then, as shown in FIG. 2B, the Ga₂O₃ substrate 10 with the scribe lines 60 is divided (or cleaved) into strips with a size according to the scribed width by breaking to form bars 10A.

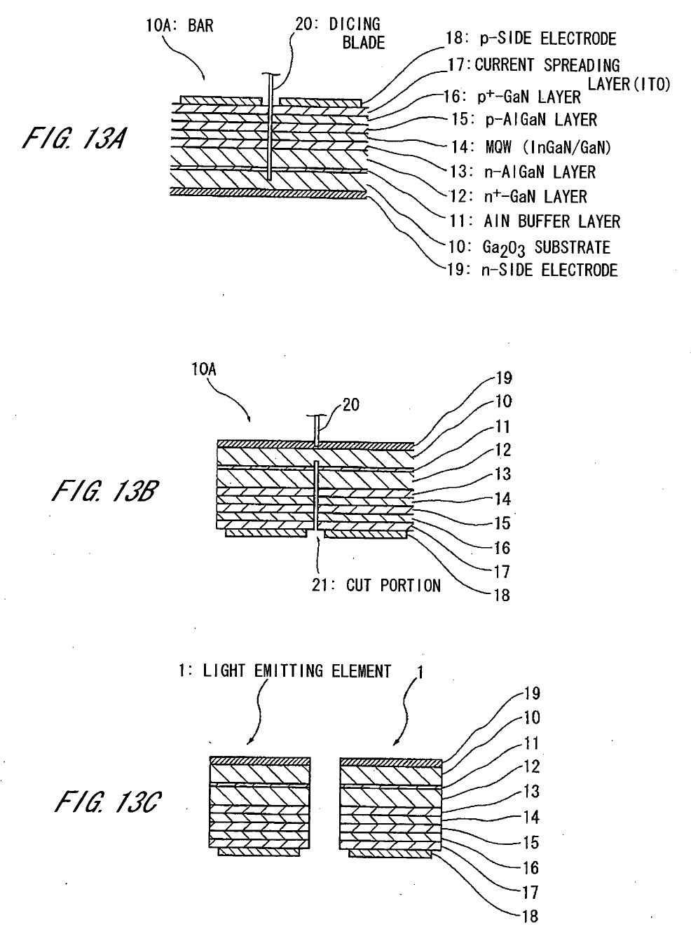

FIGS. 13A to 13C are cross sectional views showing a process that the bar (or strip) with Ga₂O₃ substrate is divided into chips.

First, as shown in FIG. 13A, a groove (=cut portion 21) is formed, in the bar 10A, to have a depth from the p-side electrode 18 to about half the thickness of the Ga₂O₃ substrate 10 by using a dicing blade 20 of diamond and with a thickness of 20 μm.

Then, as shown in FIG. 13B, the bar 10A is reversed, the dicing blade 20 is positioned corresponding to the cut portion 21 formed as shown in FIG. 13A, and another groove is formed in the p-side electrode 19 and the Ga₂O₃ substrate 10 from the opposite side to the cut portion 21 by using the dicing blade 20.

By grooving the bar 10A thus, the bar 10A is divided into the light emitting elements 1 as shown in FIG. 13C.

Effects of the Third Embodiment

In the third embodiment, the Ga₂O₃ substrate 10 (in bar form) with the GaN-based semiconductor layers is in the stepwise fashion, not in single step, divided by the dicing blade 20. Thereby, the generation of cleavage can be prevented which is caused by the local concentration of internal stress due to the dicing. It is found by the inventors that the generation of cleavage can be prevented by dicing the substrate in both directions (or in opposite directions) in the thickness of the substrate and by dicing about half the thickness of the substrate in each dicing step. Also, it is found that the dicing depth d (for each dicing step) is effective in the range of 0.2t≦d≦0.8t where t is the thickness of the substrate.

Although in this embodiment the electrode structure of the light emitting element 1 is vertical, it may be horizontal. In the latter case, the step of reversing the wafer is not necessary in the electrode forming process.

In the third embodiment, the bar 10A, which is formed by cleaving the Ga₂O₃ substrate 10 (in wafer form) with the GaN-based semiconductor layers, is divided into the chips by dicing in the opposite directions in the thickness of the bar 10A. However, the dicing can be in the same direction in the thickness of the bar 10A.

### Fourth Embodiment

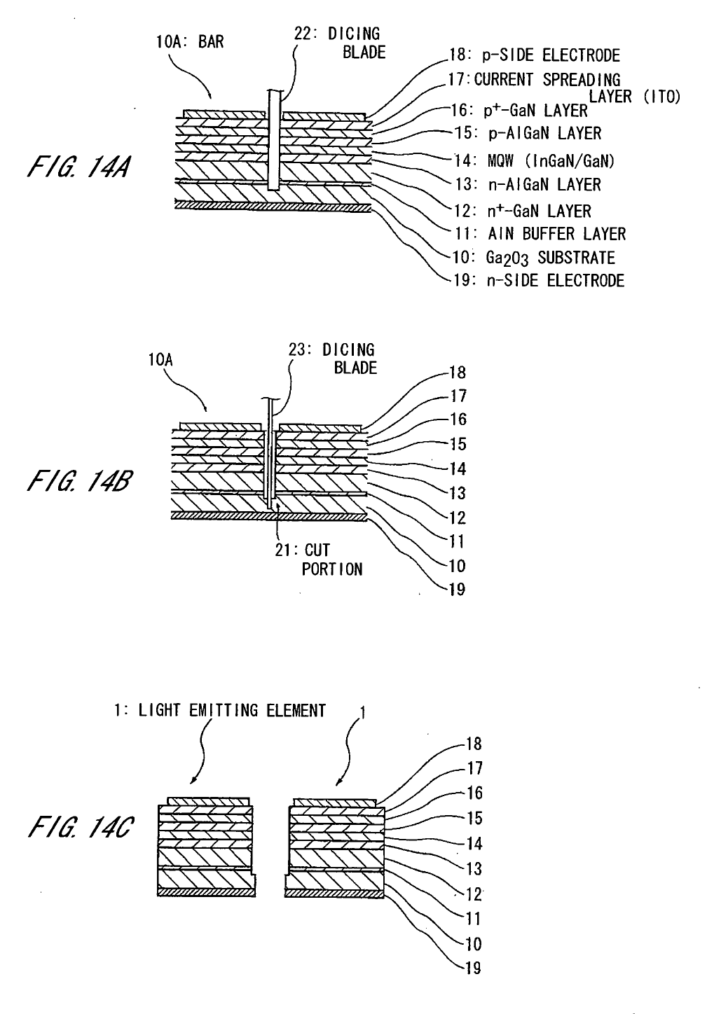

FIGS. 14A to 14C are cross sectional views showing a method of making a semiconductor element in the fourth preferred embodiment of the invention.

First, as shown in FIG. 14A, a groove (=cut portion 21) is formed, in the bar 10A, to have a depth from the p-side electrode 18 to about half the thickness of the Ga₂O₃ substrate 10 by using a dicing blade 22 of diamond and with a first thickness of 50 μm.

Then, as shown in FIG. 14B, another groove is formed in the remaining thickness of the Ga₂O₃ substrate 10 and the p-side electrode 19 from the bottom of the cut portion 21 to the bottom surface of the bar 10A by using a dicing blade 23 of diamond and with a second thickness of 20 μm, which is thinner than that of the first dicing blade 22.

By grooving the bar 10A thus, the bar 10A is divided into the light emitting elements 1 as shown in FIG. 14C.

Effects of the Fourth Embodiment

In the fourth embodiment, the Ga₂O₃ substrate 10 (in bar form) with the GaN-based semiconductor layers is in the stepwise fashion, not in single step, divided such that after grooving it to half the thickness of the substrate by using the dicing blade 22, it is subsequently grooved to the bottom surface thereof by using the dicing blade 23 with the thinner thickness. Thereby, the generation of cleavage can be prevented which is caused by the local concentration of internal stress due to the dicing.

### Other Embodiment

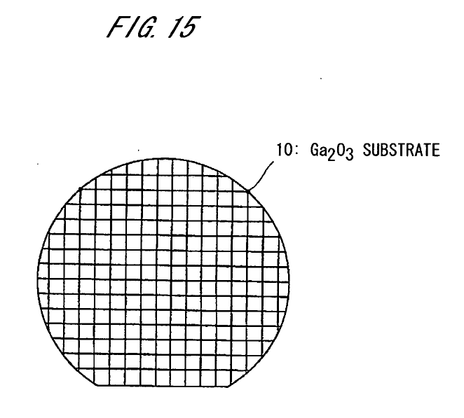

FIG. 15 is a plain view showing a modification of the third or fourth embodiment. Although in the third and fourth embodiments the strip bar 10A is divided by dicing, the Ga₂O₃ substrate 10 (in wafer form) can be divided into chips by dicing in lattice form (See FIG. 15) from the front and/or back surface thereof as taught in the third and fourth embodiments.

The invention can be applied to a light emitting element such as LED and LD, and a light receiving element such as a photodiode, a phototransistor and LDR.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A method of making a semiconductor element that comprises a substrate formed of gallium oxide and a semiconductor layer formed on the substrate, comprising:
a first dividing step that the substrate with the semiconductor layer formed thereon is divided into a strip bar along a first cleaved surface of the substrate; and
a second dividing step that the strip bar is divided in a direction perpendicular to the first cleaved surface.

2. The method according to claim 1, wherein:
the semiconductor layer is formed on a plane that is perpendicular to the first cleaved surface and parallel to a second cleaved surface of the substrate.

3. The method according to claim 2, wherein:
the second dividing step comprises:
a marking step that a mark is formed on the semiconductor layer forming plane or on an plane opposite to the semiconductor layer forming plane of the strip bar; and
a dicing step that the strip bar is diced in the direction perpendicular to the first cleaved surface by using the mark as a reference position.

4. The method according to claim 3, wherein:
the marking step comprises dicing shallowly the semiconductor layer forming plane of the substrate.

5. The method according to claim 3, wherein:
the dicing step comprises a first dicing step that one cleaved surface of the strip bar is diced to a predetermined depth, and a second dicing step that an other cleaved surface opposite to the one cleaved surface of the strip bar is diced.

6. The method according to claim 1, wherein:
the semiconductor layer is formed of group III nitride-based compound semiconductor.

7. A semiconductor element, comprising:
a substrate formed of gallium oxide and comprising a predetermined plane direction; and
a semiconductor layer formed on the substrate,
wherein the semiconductor element is in chip form and further comprises a first end face formed along a cleaved surface of the substrate and a second end face formed perpendicular to the first end face, and
the first end face comprises a stronger cleavage property than the second end face.

8. The semiconductor element according to claim 7, wherein:
the substrate is formed of β-Ga₂O₃.

9. The semiconductor element according to claim 7, wherein:
the second end face is formed by dicing.

10. The semiconductor element according to claim 7, wherein:
the second end face is formed by a laser processing to irradiate a laser light with a predetermined wavelength.

11. The semiconductor element according to claim 7, wherein:
the predetermined plane direction comprises at least one of (100), (001), (010) and (801) plane directions.

12. A method of making a semiconductor element, comprising the steps of:
forming a semiconductor layer on a gallium oxide substrate with a predetermined plane direction;
cleaving the gallium oxide substrate into a strip bar along a cleaved surface thereof; and
cutting the strip bar in a direction perpendicular to the cleaved surface by using a process except the cleaving.

13. The method according to claim 12, wherein:
the process comprising a dicing process.

14. The method according to claim 12, wherein:
the process comprising a laser processing to irradiate a laser light with a predetermined wavelength.

15. The method according to claim 14, wherein:
the predetermined wavelength comprises a wavelength of less than 400 nm.

16. The method according to claim 14, wherein:
the predetermined wavelength comprises a wavelength obtained by the laser light comprising a YAG third harmonic wave or excimar laser.

17. The method according to claim 12, wherein:
the predetermined plane direction comprises at least one of (100), (001), (010) and (801) plane directions.

18. A method of making a semiconductor element, comprising:
an element forming step that a first conductivity type semiconductor layer and a second conductivity type semiconductor layer are on a substrate formed of gallium oxide (Ga₂O₃); and
a dicing step that the substrate with the first and second conductivity type semiconductor layers is divided into the semiconductor element by applying a plurality of dicing processes for each diced portion.

19. A method of making a semiconductor element, comprising:
an element forming step that a first conductivity type semiconductor layer and a second conductivity type semiconductor layer are on a substrate formed of gallium oxide (Ga₂O₃);
a first dicing step that the substrate is diced in a first direction; and
a second dicing step that the substrate is diced in a second direction opposite to the first direction such that the substrate with the first and second conductivity type semiconductor layers is divided into the semiconductor element.

20. A method of making a semiconductor element, comprising:
an element forming step that a first conductivity type semiconductor layer and a second conductivity type semiconductor layer are on a substrate formed of gallium oxide (Ga₂O₃);
a first dicing step that the substrate is diced at a first dicing width in a first direction; and
a second dicing step that the substrate is diced with a second dicing width in the first direction such that the substrate with the first and second conductivity type semiconductor layers is divided into the semiconductor element.

21. The method according to claim 19, wherein:
the first and second dicing steps are conducted with a same dicing width.

22. The method according to claim 20, wherein:
the first dicing width is greater than the second dicing width.
